(19) United States
(12) Patent Application Publication
(10) Pub. No.: US 2016/0282483 A1
(43) Pub. Date: Sep. 29, 2016

(54) SCINTILLATOR PANEL, RADIATION DETECTOR, AND METHOD FOR MANUFACTURING SCINTILLATOR PANEL

(71) Applicant: Konica Minolta, Inc., Tokyo (JP)

(72) Inventors: Tadashi ARIMOTO, Tokyo (JP); Keiko ITAYA, Tokyo (JP)

(21) Appl. No.: 15/075,968

(22) Filed: Mar. 21, 2016

(30) Foreign Application Priority Data
Mar. 27, 2015 (JP) 2015-066674

(51) Int. Cl. G01T 1/20; G03F 7/20; G03F 7/26

(52) U.S. Cl. CPC G01T 1/2012; G01T 1/2018; G03F 7/26; G03F 7/2022

(57) ABSTRACT

A scintillator panel including a substrate and a scintillator layer provided on the substrate, the layer including a plurality of columnar structures, wherein the plurality of columnar structures are independent of each other via a gap, and the columnar structures are irradiation products.

### CROSS-REFERENCE TO RELATED APPLICATIONS

The present application is an application claiming priority to Japanese Patent Application No. 2015-066674, filed Mar. 27, 2015, under the Paris Convention. The contents of these applications are incorporated herein by reference in their entirety.

### BACKGROUND OF THE INVENTION

1. Field of the Invention

The present invention relates to a scintillator panel, a radiation detector, and a method for manufacturing a scintillator panel.

2. Discussion of the Background

Conventionally, X-ray images on films have been widely used in medical and other facilities. Such X-ray images on films are still used today for their high accuracy.

X-ray images on films, however, are analog image information and therefore cannot be used in digital radiation detectors, such as computed radiography (CR) and flat panel detectors (FPDs), which have increasingly been used in recent years.

In FPDs, scintillator panels have been used to convert radiation into visible light. These scintillator panels include X-ray phosphors such as cesium iodide (CsI), and the X-ray phosphors emit visible light in response to X-rays applied. The visible light thus emitted is converted into an electrical signal using, for example, a thin film transistor (TFT) or a charge-coupled device (CCD), thereby converting the information of the X-rays into digital image information.

FPDs, however, have the disadvantage of low S/N ratios. One possible reason for this is that when an X-ray phosphor emits visible light, the X-ray phosphor itself scatters the light.

To reduce the scattering of visible light, proposed are techniques of filling an X-ray phosphor into cells divided by a barrier rib (JP-A-2013-140036, WO 2014/054422, WO 2014/080816, JP-A-2014-029314, and Japanese Patent No. 5488773).

The barrier rib used in these techniques has a structure in which thin plate-like walls having widths in the range of about 5 to 40 μm and heights in the range of about 100 to 800 μm are combined.

Examples of the method of forming such a barrier rib include etching of a silicon wafer and a method in which a glass paste, a mixture of low-melting-point glass powder and a UV-curable resin, is applied to a substrate, and a barrier rib is formed by photolithography (JP-A-2014-029314 and Japanese Patent No. 5488773).

In the etching of a silicon wafer, however, the size of formable scintillator panels are limited by the size of silicon wafers, and a scintillator panel having a large size of, for example, 500 mm square cannot be formed. A scintillator panel having a large size can be formed by placing numbers of small-size panels, but this approach is not suitable for forming a scintillator panel having a large size because of difficulty in formation with accuracy.

The photolithography using a glass paste can form a large-size barrier rib with high accuracy, but unfortunately, the photolithography requires a firing step, and therefore a barrier rib cannot be formed on a low-heat-resistant substrate such as a sensor substrate including TFT/PD (photodiode) and other components.

In addition to the above methods of forming a scintillator layer in cells divided by a barrier rib, a method is proposed in which a scintillator layer is cut to form a groove, into which a curable resin is filled to form a barrier rib (WO 2013/146304).

The method described in WO 2013/146304, however, has the disadvantages of degradation of scintillator properties due to damage by cutting and low productivity due to time-consuming cutting.

The above-described methods using a barrier rib share the same requirements, that is, the barrier rib, for higher strength, should have a certain width to prevent collapse defects of the barrier rib, but as the barrier rib width increases, the space between the barrier ribs decreases relatively, resulting in a reduced volume of an X-ray phosphor that can be filled and ununiform filling. On the other hand, the barrier rib width cannot be below a certain level in terms of strength. Accordingly, scintillator panels formed by this method emit light weakly because of the reduced amount of X-ray phosphor, which is a big problem particularly in low-dose photographing.

Thus, to provide high light emission efficiency and clear image quality, it is desired that the scintillator panel have a large size and can be processed with high accuracy, the barrier rib width be as thin as possible, and light not leak from the scintillator panel.

To reduce the scattering of visible light, disclosed is a technique of forming a scintillator layer having a structure of independent columns using screen printing by applying a paste containing phosphor particles to a substrate at given portions (JP-A-2002-139570).

In the method in JP-A-2002-139570, it is theoretically difficult to form a fine columnar structure of a usual pixel size (the area of the columnar structure viewed from above the substrate is 10 μm×10 μm to 300 μm×300 μm) because of the influence of the mesh of a screen printing plate. Another problem is that the paste containing phosphor particles, during the process of leveling, isotropically wets and spreads on the substrate to unite with adjacent columnar structures, resulting in reduced sharpness. To avoid these problems, it is necessary to secure in advance a sufficient gap between the columnar structures, but a sufficient gap width necessarily reduces the filling rate of the scintillator layer, causing another problem of a reduction in brightness.

### SUMMARY OF THE INVENTION

According to one aspect of the present invention, a scintillator panel comprises a substrate and a scintillator layer provided on the substrate. The layer comprises a plurality of columnar structures, wherein the plurality of columnar structures are independent of each other via a gap, and the columnar structures are irradiation products.

According to another aspect of the present invention, a radiation detector comprises a sensor substrate (I) having a plurality of light-receptive pixels and the scintillator panel, or a radiation detector comprises the scintillator panel wherein the substrate is a sensor substrate (I) having a plurality of light-receptive pixels; and a substrate (II) on which a plurality of light-receptive pixels are not formed.

According to further aspect of the present invention, a method for manufacturing a scintillator panel comprises forming a photosensitive paste layer from a photosensitive paste comprising at least scintillator particles and a photosensitive component, and exposing the photosensitive paste layer using a photomask to forma given pattern; and removing developer-soluble portions of the exposed photosensitive paste layer.

### BRIEF DESCRIPTION OF DRAWINGS

FIG. 1 is a schematic diagram illustrating an example of a sensor substrate: and

FIG. 2 is a schematic diagram illustrating an example of a circuit of a unit pixel PX (pixel circuit 20) in FIG. 1.

### DESCRIPTION OF THE EMBODIMENTS

The scintillator panel of the embodiment of the present invention is characterized by including a substrate and a scintillator layer provided on the substrate, the layer including a plurality of columnar structures, wherein the plurality of columnar structures are independent of each other via a gap, and the columnar structures are irradiation products.

The scintillator panel of the embodiment of the present invention is preferably a laminate of a plurality of resin layers each containing scintillator particles and a resin.

Furthermore, the scintillator panel of the embodiment of the present invention preferably satisfies the relationships 0.1≦B/A≦20.0 and 2.0≦C/A, wherein A is an interval (μm) between the adjacent columnar structures; B is a length (μm) of one of the resin layers constituting a columnar structure in the direction in which the substrate and the resin layers are laminated; and C is a diameter (μm) of the inscribed circle of a columnar structure viewed from above the substrate.

In the scintillator panel of the embodiment of the present invention, B, the length of one of the resin layers constituting a columnar structure in the direction in which the substrate and the resin layers are laminated, is preferably in the range of 10 to 200 μm.

The radiation detector of the embodiment of the present invention may be a detector including a sensor substrate (I) having a plurality of light-receptive pixels and the scintillator layer of the scintillator panel facing each other, or may be a detector including a scintillator panel including the sensor substrate (I) having a plurality of light-receptive pixels and a scintillator layer formed thereon, and a substrate (II) on which a plurality of light-receptive pixels are not formed.

A method for manufacturing the scintillator panel of the embodiment of the present invention preferably includes Step I: forming a photosensitive paste layer from a photosensitive paste containing at least scintillator particles and a photosensitive component, and exposing the photosensitive paste layer using a photomask to form a given pattern; and Step II: removing developer-soluble portions of the exposed photosensitive paste layer.

In this case, Step I is preferably repeated twice or more before Step II.

According to the embodiment of the present invention, the columnar structures each containing scintillator particles can be made independent of each other by a slight gap; fluorescence leakage from the columnar structures can certainly be prevented; and the volume (filling rate) of the columnar structures per unit area of the substrate surface can be increased; therefore, the scintillator panel of the embodiment of the present invention has significantly high brightness and sharpness.

According to the manufacturing method of the embodiment of the present invention, scintillator panels having high brightness and sharpness can be easily manufactured.

Furthermore, according to the embodiment of the present invention, large-size scintillator panels can be provided because it is possible to manufacture scintillator panels without using silicon wafers.

### 1. Scintillator Panel

The scintillator panel of the embodiment of the present invention includes a substrate (hereinafter also referred to as “substrate A”) and a scintillator layer provided on the substrate A. In the scintillator layer, a plurality of columnar structures are independent of each other via a gap, preferably a gap formed by an airspace, and the columnar structures are irradiation products formed by irradiation.

The scintillator panel of the embodiment of the present invention having such characteristics is a scintillator panel having a compartmentalized scintillator layer and very excellent image qualities, specifically, brightness and sharpness.

The phrase “a plurality of columnar structures are independent of each other via a gap” means that there is a gap between the plurality of columnar structures on the substrate, and the columnar structures are not in contact with each other neither at the bottom (the substrate side) nor the top.

The scintillator panel of the embodiment of the present invention, because of the scintillator layer in which a plurality of columnar structures are independent of each other via a gap, is a panel that scatters little visible light and has high brightness and sharpness.

The phrase “the columnar structures are irradiation products” means that the columnar structures are formed by a method involving irradiation, preferably, photolithography.

Examples of the radiation applied include a wide range of electromagnetic waves from visible light to X-rays.

Since the columnar structures are irradiation products, a scintillator panel can be formed that has a scintillator layer of the desired shape, in particular, a scintillator layer including a plurality of columnar structures independent of each other via the desired gap.

To form a scintillator panel having a scintillator layer of the desired shape, in particular, a scintillator layer including a plurality of columnar structures independent of each other via the desired gap, the columnar structures are preferably each a laminate of a plurality of resin layers each containing scintillator particles and a resin.

In this case, A and B preferably satisfies the relationship 0.1≦B/A≦20.0, more preferably 0.5≦B/A≦10.0, further more preferably 5.0≦B/A≦10.0, and A and C preferably satisfies the relationship 2.0≦C/A, more preferably 3.0≦C/A, wherein A is an interval (μm) between the adjacent columnar structures; B is a length (μm) of one of the resin layers constituting a columnar structure in the direction in which the substrate and the resin layers are laminated; and C is a diameter (μm) of the inscribed circle of a columnar structure viewed from above the substrate.

A, B, and C can be determined from a micrograph obtained by observing the scintillator panel under a microscope.

The interval A is an average of the intervals between the centers of adjacent columnar structures. For example, in the case of a scintillator panel having three columnar structures wherein a columnar structure 1, a columnar structure 2, and a columnar structure 3 are arranged in this order on the substrate A, the interval A is expressed as (X+Y)/2 wherein X is the shortest distance between the center in the height direction of the columnar structure 1 and the center in the height direction of the columnar structure 2, and Y is the shortest distance between the center in the height direction of the columnar structure 2 and the center in the height direction of the columnar structure 3.

The length B, when the columnar structure is a laminate of a plurality of resin layers each containing scintillator particles and a resin, is a thickness (a length in the direction in which the substrate and the resin layers are laminated) of one resin layer (base lamination unit).

It is noted that the plurality of resin layers constituting each columnar structure may have different thicknesses, and in this case, the length B is a thickness of the thinnest resin layer among the plurality of resin layers constituting each columnar structure.

The diameter C is a diameter of the inscribed circle of a columnar structure viewed from above the substrate, i.e., viewed from the scintillator layer side of the scintillator panel. It is noted that when the plurality of columnar structures included in the scintillator panel have different diameters, the diameter C is an average of these diameters.

When the columnar structures are opposed one-to-one to pixels of a sensor, the pixel size is typically A+C.

The interval A is typically 3 to 100 μm, preferably 5 to 50 μm. The length B is typically 10 to 200 μm, preferably 25 to 100 μm. The diameter C is typically 10 to 500 μm, preferably 50 to 250 μm.

The interval A in the above range enables an increased volume (filling rate) of columnar structures per unit area of the substrate surface, which leads to a scintillator panel with high brightness, and prevents adjacent columnar structures from uniting with each other, which leads to a scintillator panel with high sharpness.

The length B in the above range, in the exposure in Step I described below, enables sufficient exposure of portions to be exposed, as a result of which the desired columnar structures can be readily formed, and scintillator panels can be produced with high productivity.

For these reasons, the B/A in the above range results in a good balance between the image quality of the scintillator panel to be obtained and productivity.

The C/A in the above range results in a radiation detector in which pixels of a sensor are sufficiently covered with a scintillator layer, and hence a radiation detector with high brightness.

When the columnar structures included in the scintillator panel have the shape and configuration as described above, the columnar structures formed in the scintillator panel can be made independent of each other by a slight gap; fluorescence leakage from the columnar structures can certainly be prevented; and the filling rate (volume) of the columnar structures per unit area of the substrate surface can be increased; therefore, the scintillator panel of the embodiment of the present invention has significantly high brightness and sharpness.

In addition, the scintillator panel preferably has a scintillator layer in which the columnar structures are regularly arranged.

The scintillator panel of the embodiment of the present invention may be any panel that has a substrate and a scintillator layer, and may optionally have conventionally known layers such as a reflecting layer.

When a substrate (II) described below is used as the substrate A, it is preferable to form a reflecting layer on the substrate (II) because light emitted from the scintillator is reflected and guided efficiently to a sensor, resulting in improved brightness. Alternatively, if the columnar structures are formed using, for example, a photosensitive paste containing a powder component such as titanium oxide powder or aluminum oxide powder, a part of the columnar structures can be used as a reflecting layer. Furthermore, a reflecting layer provided on the side of the columnar structures can advantageously guide light emitted from the scintillator to a sensor with higher efficiency.

The reflecting layer may be formed by any method, and various layer-forming methods can be used, e.g., applying a paste-like reflective material to the surface, followed by removing a solvent and other components by firing, spraying a reflective material, and other methods. In particular, vacuum layer formations such as vacuum deposition, sputtering, ion plating, CVD, and laser ablation are preferred because a uniform reflecting layer can be formed at lower temperatures, and sputtering is more preferred because a uniform layer can be formed on the side of the columnar structures.

When a substrate (I) described below is used as the substrate A, it is preferable to form a reflecting layer on the surface of the scintillator layer (the scintillator layer surface opposite to the substrate). This can prevent light emitted from the scintillator in a columnar structure from propagating to adjacent columnar structures via airspace, leading to improved sharpness. In addition, light emitted from the scintillator is reflected and efficiently guided to a sensor, leading to improved brightness.

### 1.1 Substrate

The substrate A may be any substrate that transmits radiation, and various substrates such as glass substrates, polymeric substrates, and metal substrates can be used. Examples include glass substrates made of glass components such as quartz, borosilicate glass, and chemically strengthened glass;

ceramic substrates made of ceramics such as sapphire, silicon nitride, and silicon carbide;

semiconductor substrates made of semiconductors such as silicon, germanium, gallium arsenide, gallium phosphide, and gallium silicon;

polymer films such as cellulose acetate films, polyester films, polyethylene terephthalate films, polyamide films, polyimide films, polycarbonate films, and carbon fiber-reinforced resin sheets;

metal sheets such as aluminum sheets, iron sheets, and copper sheets;

metal sheets having coating layers of metal oxides; and amorphous carbon substrates. Of these, glass substrates or polymer films are suitable for use.

The substrate A may be a substrate (II) on which a plurality of light-receptive pixels are not formed, or may be a sensor substrate (I) having a plurality of light-receptive pixels, on which CCD, CMOS, TFT/PD, or any other device is formed.

The thickness of the substrate A may be any thickness that does not hinder the radiation transmittance, and is typically 10 to 2000 μm, preferably 10 to 1000 μm.

### 1.2 Columnar Structure

The columnar structures preferably each contain scintillator particles and a resin, and are preferably each a laminate of a plurality of resin layers containing scintillator particles and a resin as main components. As used herein, the term “main component” refers to a component that accounts for at least 50% by mass of 100% by mass of the resin layer.

To provide a scintillator layer having high mechanical strength and light emission intensity, the resin layer contains scintillator particles preferably in an amount of 20% to 95% by volume, more preferably 40% to 80% by volume, and contains a resin preferably in an amount of 5% to 80% by volume, more preferably 20% to 60% by volume.

### 1.2.1 Photosensitive Paste

The columnar structures are preferably formed using a photosensitive paste containing at least scintillator particles and a photosensitive component and preferably contains a cured product of scintillator particles and a photosensitive component.

The presence of a photosensitive component in the photosensitive paste allows the resulting photosensitive paste layer to be patterned by photolithography.

Various known particles can be used as the scintillator (phosphor) particles. Specific examples include, but are not limited to, particles containing CsI, Gd₂O₂S, Lu₂O₂S, Y₂O₂S, LaCl₃, LaBr₃, LaI₃, CeBr₃, CeI₃, LuSiO₅, Ba (Br, F, Zn), and the like, which convert X-rays to visible light at a high rate. These can be used alone or in a combination of two or more.

The scintillator particles may contain various activators to enhance the light emission efficiency. For example, when containing CsI, the scintillator particles preferably contain an activating material such as sodium iodide (NaI), indium (In), thallium (Tl), lithium (Li), potassium (K), rubidium (Rb), or sodium (Na). Thallium compounds such as thallium bromide (TlBr), thallium chloride (TlCl), and thallium fluoride (TlF, TlF₃) can also be used as activators. Gd₂O₂S is preferably activated by terbium (Tb).

The average particle size of the scintillator particles is typically 0.005 to 50 μm, preferably 0.1 to 20 μm. Scintillator particles having an average particle size in this range prevent or reduce the reduction in shaping accuracy due to light scattering in the exposure process in Step I (described later) in manufacturing a scintillator panel, leading to a scintillator panel having excellent light emission properties.

Examples of photosensitive components include components containing photosensitive compounds, such as photosensitive monomers, photosensitive oligomers, and photosensitive polymers, and photopolymerization initiators and the like, the use of which, for example, provides controlled reactivity. As used herein, the term “photosensitive” means undergoing a reaction such as photocrosslinking or photopolymerization upon exposure to radiation to bring about a change in chemical structure.

Examples of photosensitive monomers include compounds having active carbon-carbon double bonds, specifically, monofunctional compounds and polyfunctional compounds having vinyl, acryloyl, methacryloyl, or acrylamide as a functional group.

Such photosensitive monomers can be used alone or in a combination of two or more.

The photosensitive monomer preferably contains, particularly, 10% to 80% by mass of a polyfunctional (meth)acrylate compound in the photosensitive compound to increase the crosslink density in curing by photoreaction, providing benefits such as improvements in pattern formability. For the polyfunctional (meth)acrylate compound, one which is appropriate in terms of reactivity, refractive index, and other properties can be selected from various types of developed compounds.

As the photosensitive oligomer and the photosensitive polymer (hereinafter these are also referred to as a “photosensitive resin” collectively), oligomers and polymers having active carbon-carbon double bonds are suitable for use.

Such photosensitive resins can be used alone or in a combination of two or more.

Such photosensitive resins can be prepared by (co)polymerizing a monomer(s) using an initiator such as azobisisobutyronitrile, the monomer(s) being selected from, for example, carboxyl group-containing monomers such as acrylic acid, methacrylic acid, itaconic acid, crotonic acid, maleic acid, fumaric acid, and vinyl acetic acid; anhydrides of these acids; and other monomers such as methacrylic acid esters, acrylic acid esters, styrene, acrylonitrile, vinyl acetate, and 2-hydroxy acrylate.

The photosensitive resin may be an oligomer or polymer resin into which active carbon-carbon double bonds are introduced, and one example of the method of introduction is reacting mercapto groups, amino groups, hydroxyl groups, or carboxyl groups in the oligomer or polymer with an ethylenically unsaturated compound having a glycidyl group or isocyanate group or with acrylic acid chloride, methacrylic acid chloride, allyl chloride, or carboxylic acid such as maleic acid.

Among the above photosensitive resins, copolymers having carboxyl groups are preferred, and copolymers copolymerized from acrylic acid esters or methacrylic acid esters and acrylic acids or methacrylic acids are suitable for use for their low decomposition temperatures. Furthermore, copolymers having carboxyl groups may optionally have pendant ethylenically unsaturated groups. Examples of ethylenically unsaturated groups include acrylic, methacrylic, vinyl, and allyl.

Using a copolymer having a carboxyl group as a photosensitive resin provides a paste highly soluble in aqueous alkaline solutions.

The acid value of the copolymer having a carboxyl group is preferably 50 to 150 mg KOH/g. Using a copolymer having an acid value of not more than 150 mg KOH/g widens the allowable development width. Using a copolymer having an acid value of not less than 50 mg KOH/g prevents or reduces the reduction in the solubility of unexposed portions in a developer in Step II described later. Accordingly, it is not necessary to increase the developer concentration in Step II, which prevents exposed portions from peeling off a substrate, leading to high-definition columnar structures.

In the embodiment of the present invention, using a monomer or oligomer having a urethane bond as a photosensitive resin provides a photosensitive paste layer less prone to pattern defects in a curing step. In addition, using a compound having a urethane bond alleviates the stress during the process of decomposition and distillation of organic components in the early stage of the curing step, which advantageously reduces the likelihood of pattern defects. By virtue of these two effects, pattern defects can be reduced over a wide temperature range.

Examples of photopolymerization initiators include compounds that generate radicals upon exposure to radiation. Specific examples include benzophenone, methyl o-benzoyl benzoate, 4,4-bis(dimethylamino)benzophenone, 4,4-bis(diethylamino)benzophenone, 4,4-dichlorobenzophenone, 4-benzoyl-4-methyl diphenyl ketone, 2,4,6-trimethylbenzoyl-diphenyl-phosphine oxide, dibenzyl ketone, fluorenone, 2,2-dimethoxy-2-phenylacetophenone, 2-hydroxy-2-methylpropiophenone, thioxanthone, 2-methylthioxanthone, 2-chlorothioxanthone, 2-isopropylthioxanthone, diethylthioxanthone, benzil, benzylmethoxyethyl acetal, benzoin, benzoin methyl ether, benzoin butyl ether, anthraquinone, 2-t-butylanthraquinone, anthrone, benzanthrone, dibenzosuberone, methyleneanthrone, 4-azidobenzalacetophenone, 2,6-bis(p-azidobenzylidene)cyclohexanone, 2,6-bis(p-azidobenzylidene)-4-methylcyclohexanone, 1-phenyl-1,2-butadione-2-(o-methoxycarbonyl)oxime, 1-phenyl-1,2-propanedione-2-(o-ethoxycarbonyl)oxime, 1,3-diphenylpropanetrione-2-(o-ethoxycarbonyl)oxime, 1-phenyl-3-ethoxypropanetrione-2-(o-benzoyl)oxime, Michler's ketone, 2-methyl-1-[4-(methylthio)phenyl]-2-morpholino-1-propanone, 2-benzyl-2-dimethylamino-1-(4-morpholinophenyl)butanone-1, naphthalenesulfonyl chloride, quinolinesulfonyl chloride, N-phenylthioacridone, benzthiazole disulfide, triphenylphosphine, benzoin peroxide, and combinations of photoreducible dyes, such as eosin and methylene blue, and reducing agents, such as ascorbic acid and triethanolamine. These can be used alone or in a combination of two or more.

The photopolymerization initiator is added preferably, but not necessarily, in an amount in the range of 0.05% to 30% by mass, more preferably 0.1% to 20% by mass, based on the amount of photosensitive component. When the amount of photopolymerization initiator is in this range, a photosensitive paste layer having a sufficient photosensitivity is formed in Step I (described later) in manufacturing a scintillator panel, leading to columnar structures having the desired shape, specifically, columnar structures wherein the length B and the interval A are in the desired ranges.

The photosensitive paste may optionally contain UV absorbers. The presence of UV absorbers provides high-aspect-ratio, high-definition, and high-resolution columnar structures.

Preferred UV absorbers used here are organic dyes, and in particular, organic dyes having a high UV absorption coefficient in a wavelength range of 350 to 450 nm are suitable for use. Organic dyes are preferred because they can be removed during the process of forming columnar structures.

Specific examples of organic dyes that can be used include azo dyes, aminoketone dyes, xanthene dyes, quinoline dyes, aminoketone dyes, anthraquinone dyes, benzophenone dyes, diphenyl cyanoacrylate dyes, triazine dyes, and p-aminobenzoic acid dyes. Of these, azo dyes and benzophenone dyes are preferred.

The UV absorber is added preferably, but not necessarily, in the range of 0.1% to 60% by mass, more preferably 0.1% to 30% by mass, based on the amount of photosensitive component. The relationship between the amount of UV absorber and the shape of the resulting columnar structures also depends on the absorption wavelength of the UV absorber.

The photosensitive paste can be produced by blending various components at a given composition with an organic solvent and a binder optionally added and then mixing and dispersing the blending uniformly using a triple roll or a kneader.

The viscosity of the photosensitive paste can be appropriately adjusted by selecting the ratio of additives such as inorganic powder, thickeners, organic solvents, polymerization inhibitors, plasticizers, and antisettling agents, and it is preferably in the range of 2 to 200 Pa·s. For example, when the photosensitive paste is applied to a substrate by spin coating, viscosities of 2 to 5 Pa·s are preferred. When a method such as blade coating or die coating is used, viscosities of 10 to 50 Pa·s are preferred.

### 2. Method for Manufacturing Scintillator Panel

The scintillator panel is preferably manufactured by applying the above-described photosensitive paste to a substrate and forming the desired columnar structures by photolithography. One example of forming columnar structures by photolithography using the above-described photosensitive paste will be described below, but this example is not intended to limit the present invention.

A method for manufacturing the scintillator panel preferably includes Step I: forming a photosensitive paste layer from a photosensitive paste containing at least scintillator particles and a photosensitive component, and exposing the photosensitive paste layer using a photomask to form a given pattern; and Step II: removing developer-soluble portions of the exposed photosensitive paste layer.

According to this method, a scintillator panel of the desired shape having high brightness and sharpness can be easily formed.

### 2.1 Step I

In Step I, a photosensitive paste layer is first formed on the whole or part of a substrate using a photosensitive paste, preferably, by applying the photosensitive paste. For the application, a method such as bar coating, roll coating, die coating, or blade coating can be used.

The thickness of the photosensitive paste layer to be formed can be adjusted by selecting the number of applications, paste viscosity, and other conditions.

Subsequently, an exposure step is performed. The exposure step is typically carried out through a photomask as in usual photolithography. Alternatively, without using a photomask, a pattern may be directly formed using, for example, a laser beam.

As an exposure apparatus, a proximity exposure machine or any other machine can be used. In a large-area exposure, a large area can be exposed using a small-area exposure machine by applying a photosensitive paste to a substrate and then exposing the applied substrate while being conveyed. Examples of radiations used in this exposure include near infrared radiation, visible radiation, and ultraviolet radiation. Of these, ultraviolet radiation is preferred, and as a light source of ultraviolet radiation, for example, a low-pressure mercury lamp, a high-pressure mercury lamp, an ultra-high-pressure mercury lamp, a halogen lamp, or a germicidal lamp can be used, among which the ultra-high pressure mercury lamp is preferred.

Exposure conditions vary depending on the thickness of a photosensitive paste layer to be formed, and typically, the exposure is carried out for 0.01 to 30 minutes using an ultra-high pressure mercury lamp with a power of 1 to 100 mW/cm².

To easily form a scintillator panel of the desired shape having high brightness and sharpness, Step I is preferably repeated twice or more, specifically, 2 to 20 times, more preferably 2 to 10 times.

When Step I is repeated twice or more, it is preferable to form a photosensitive paste on a substrate layer in the first run of Step I and form another photosensitive paste layer on the exposed photosensitive paste layer in the second and subsequent runs of Step I.

### 2.2 Step II

The exposed photosensitive paste layer obtained in Step I is developed utilizing the difference in solubility in a developer between exposed portions and unexposed portions to yield a resin layer of the desired shape (e.g., grid-like). The development can be carried out, for example, by immersion, spraying, or brushing.

For the developer, solvents capable of dissolving the photosensitive component in the photosensitive paste layer can be used. When a compound having an acidic group such as carboxyl is present in the photosensitive paste layer, aqueous alkaline solutions can be used for development. Although aqueous solutions of inorganic alkalis such as sodium hydroxide, sodium carbonate, and calcium hydroxide can be used as aqueous alkaline solutions, organic aqueous alkaline solutions are preferred because the alkaline component contained in the developer is readily removed from the developed resin layer. Examples of organic alkalis include tetramethylammonium hydroxide, trimethylbenzylammonium hydroxide, monoethanolamine, and diethanolamine. The concentration of the alkaline component in the aqueous alkaline solution is preferably 0.05% to 5% by mass, more preferably 0.1% to 1% by mass. Too low a concentration of the alkaline component may result in difficulty in removing soluble part of the exposed photosensitive paste layer, whereas too high a concentration of the alkaline component tends to cause insoluble part of the exposed photosensitive paste layer to be peeled from the substrate, which may lead to the corrosion of the insoluble part.

The temperature during the development is preferably from 20° C. to 50° C. in terms of process control.

In the development, it is preferable to use an alkaline developer with a pH of 8 to 13 or an organic solvent capable of dissolving an unexposed photosensitive paste layer.

The width of a gap formed by washing away with a developer (the interval between adjacent columnar structures) is typically in the range of 3 to 100 μm, preferably 5 to 50 μm.

The length of one of the resin layers obtained through Step I in the direction in which the substrate and the resin layers are laminated is preferably about 10 to 200 μm, more preferably about 25 to 100 μm. Since each columnar structure preferably has a thickness of about 200 to 1000 μm, if the thickness of one resin layer is below this range, it is preferable to perform Step I several times until the predetermined thickness is reached.

When a scintillator layer is formed on a substrate, the scintillator layer may be directly formed on the substrate (I) or (II) using a photosensitive paste, or for example, when a scintillator layer is formed on the substrate (I), a scintillator layer formed in advance on the substrate (II) may be transferred to the surface of the substrate (I).

### 3. Radiation Detector

The radiation detector of the embodiment of the present invention may be a detector including the above-described scintillator panel and the sensor substrate (I) having a plurality of light-receptive pixels, that is, a detector including a scintillator panel wherein the substrate A is the substrate (II) on which a plurality of light-receptive pixels are not formed, and the sensor substrate (I) having a plurality of light-receptive pixels, or may be a detector including a scintillator panel wherein the substrate A is the sensor substrate (I) having a plurality of light-receptive pixels, and the substrate (II) on which a plurality of light-receptive pixels are not formed. In the former case, a detector is preferred in which the scintillator layer of the scintillator panel and the substrate (I) are facing each other.

Since the scintillator panel of the embodiment of the present invention has high brightness and high sharpness, radiation detectors including this panel are able to detect radiation with high brightness and high sharpness.

In general, the columnar structures in the scintillator panel are preferably opposed one-to-one to pixels of the sensor, and therefore the pitch of the pixels and that of the columnar structures desirably correspond to each other. However, if the pixel size is small, one columnar structure may be opposed to a plurality of pixels. The pixel size of the sensor is typically 10 μm×10 μm to 300 μm×300 μm.

In manufacturing the radiation detector, the scintillator panel, and the substrate (I) or the substrate (II) may be simply placed on top of each other without using an adhesive or stuck together using an adhesive. The adhesive may be any adhesive that is optically transparent, and for example, double-sided tape and thermoplastic hot-melt resins can be used.

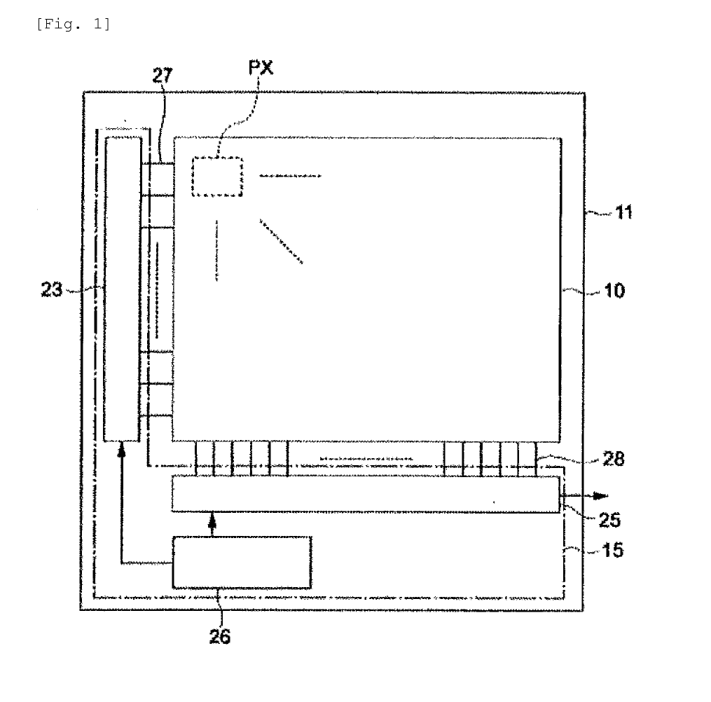

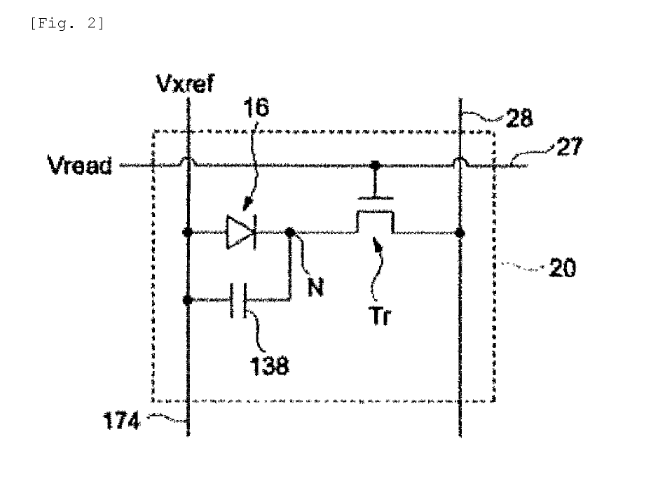

Although the sensor substrate will be described with reference to FIG. 1 and FIG. 2, the following description is for illustrative purposes only, and various modifications can be made without departing from the spirit of the present invention.

FIG. 1 schematically shows an example of a sensor substrate 11, and FIG. 2 is a schematic diagram illustrating an example of a circuit of a unit pixel PX (pixel circuit 20) in FIG. 1.

The sensor substrate 11 in FIG. 1 includes a pixel unit 10 and a circuit unit 15 configured to drive the pixel unit 10. In the pixel unit 10 in FIG. 1, a plurality of the unit pixels PX each including a photodiode 16 and a transistor Tr are arranged in a matrix. Each unit pixel PX is connected to a pixel drive line 27 (specifically, a row selection line) and a signal line 28.

The circuit unit 15 includes, for example, a row scanning unit 23, a column scanning unit 25, and a system control unit 26. The row scanning unit 23 comprises a shift register, an address decoder, and other components, and sends driving signals to the pixel unit 10 via the pixel drive lines 27 to thereby drive the pixel unit 10 row-wise. The column scanning unit 25 comprises a shift register, an address decoder, and other components. The column scanning unit 25 successively receives signals sent from the signal lines 28, which signals are dependent on the amount of received light of the photodiode 16 provided in the unit pixel PX, and output these signals to the outside.

A circuit portion comprising the row scanning unit 23, the column scanning unit 25, and the system control unit 26 may be a circuit integrated into the sensor substrate 11, or may be disposed on an external control IC connected to the sensor substrate 11. Alternatively, the circuit portion may be formed on another substrate connected, for example, via a cable.

The system control unit 26 receives information such as external clock signals or data to direct the mode of operation and also outputs data such as internal information of the radiation detector. The system control unit 26 further includes a timing generator to generate various timing signals, and controls the drive of the row scanning unit 23 and the column scanning unit 25 on the basis of the various timing signals generated by the timing generator.

The pixel circuit 20 in FIG. 2 is, for example, a circuit that employs a passive matrix driving system, and includes the photodiode 16, a capacitor 138, and the transistor Tr.

The photodiode 16 is a device that generates a signal charge with a charge amount depending on the amount of incident light (the amount of received light). The photodiode 16 and the capacitor 138 are connected to a supply line 174 of a reference unit V_{xref} in parallel. Specifically, the photodiode 16 is connected between the supply line 174 and a storage node N, an end of the capacitor 138.

A row operation signal (read signal) V_{read} is sent to the pixel drive line 27. The gate of the transistor Tr is connected to the pixel drive line 27, and a source and a drain are connected to the storage node N and the signal line 28, respectively. A voltage corresponding to the row operation signal V_{read} is applied to the gate of the transistor Tr, as a result of which a signal charge stored in the capacitor 138, the signal charge having a charge amount depending on the amount of received light of the photodiode 16, is delivered to the signal line 28 via the storage node N.

### EXAMPLES

The present invention will now be described in more detail with reference to the examples of the present invention, but these examples are not intended to limit the present invention.

### Preparing Photosensitive Paste

21 parts by mass of polypropylene glycol diacrylate as a photosensitive monomer, 1 part by mass of 2,4,6-trimethylbenzoyl-diphenyl-phosphine oxide (LUCIRIN TPO available from BASF) as a photopolymerization initiator, and 79 parts by mass of Gd₂O₂S:Tb (average particle size: 5 μm) as scintillator particles were mixed and kneaded with a triple roller kneader to prepare a photosensitive paste.

### Sample 1 (Example 1)

Onto the surface of a glass substrate (0.5-mm-thick alkali-free glass) for forming a scintillator layer, silver was sputtered as a reflecting layer. To the reflecting layer, the photosensitive paste prepared above was further applied using a die coater such that the thickness of the cured coating would be 50 μm to form a photosensitive paste layer. Next, via a photomask having openings of 185 μm×185 μm arranged in a matrix at intervals of 15 μm, the photosensitive paste layer was exposed using an ultra-high pressure mercury lamp at 700 mJ/cm². Subsequently, on the exposed photosensitive paste layer, another photosensitive paste layer was formed and exposed in the same manner as described above. This procedure was repeated eight times, and then development was performed to dissolve unexposed portions of the photosensitive paste layer with acetone, thereby manufacturing a scintillator panel having columnar structures with eight layers and a thickness (height) of 400 μm.

Next, a sensor panel in which photoelectric conversion elements, each having a pixel size of 200 μm×200 μm and comprising a photodiode and a TFT, were arranged in a matrix on a glass substrate (0.5-mm-thick alkali-free glass) for forming a sensor was provided, and the above scintillator panel was aligned with the sensor panel such that the columnar structures of the scintillator panel and the photoelectric conversion elements of the sensor panel faced each other and bonded via a 10-μm-thick adhesive layer made of a hot-melt resin to manufacture an X-ray detector.

### Samples 2 to 7 (Examples 2 to 7)

An X-ray detector was manufactured in the same manner as in Example 1 except that the conditions in Example 1 were changed as shown in Table 1.

### Sample 8 (Reference Example 1)

Onto the surface of a glass substrate (0.5-mm-thick alkali-free glass) for forming a scintillator layer, silver was sputtered as a reflecting layer. To the reflecting layer, the photosensitive paste prepared above was further applied using a die coater such that the thickness of the cured coating would be 400 μm to form a photosensitive paste layer. Next, the photosensitive paste layer was exposed using an ultra-high pressure mercury lamp at 700 mJ/cm² to manufacture a scintillator panel.

An X-ray detector was manufactured in the same manner as in Example 1 except that the scintillator panel was used.

### Evaluation Method

### Brightness

Using an X-ray irradiation apparatus with a tube voltage set to 80 kVp, X-rays were applied to the light-receiving surface of an FPD including the X-ray detector obtained in Reference Example 1. From the X-ray image data obtained, the average signal value of the entire X-ray image was determined and used as a brightness of the scintillator panel. The brightness of the scintillator panel was measured in the same manner except that the X-ray detector obtained in Reference Example 1 was replaced with the X-ray detectors obtained in Examples 1 to 7. For each sample, a value relative to the average signal value (taken as 100) in the case of using the X-ray detector obtained in Reference Example 1 was determined and evaluated according to the following criteria.

AA: 95 or greater

BB: 90 to less than 95

CC: 80 to less than 90

DD: Less than 80

### Sharpness

Using a CMOS flat panel including the X-ray detector obtained in Examples 1 to 7 or Reference Example 1, the following test was performed.

Using an X-ray irradiation apparatus with a tube voltage set to 80 kVp, X-rays were applied to the back surface (the surface on which no scintillator layer was formed) of the above scintillator panel through a lead MTF chart, and an image data detected by the CMOS flat panel was recorded on a hard disk. The record of the image data on the hard disk was then analyzed by a computer to determine the modulation transfer function (MTF) (MTF value at one spatial frequency cycle/mm) of the X-ray image recorded on the hard disk, and evaluated for sharpness according to the following criteria.

AA: 0.70 or greater

BB: 0.65 to less than 0.70

CC: 0.60 to less than 0.65

DD: Less than 0.60

### Productivity

As the number of laminations of the photosensitive paste layer (=the number of laminations of the base lamination unit in a columnar structure) increases, the time required for manufacturing increases, resulting in lower productivity. Based on the number of laminations of the photosensitive paste layer, whether the productivity was good or bad was evaluated.

AA: Less than 5 times

BB: 5 times to less than 10 times

CC: 10 times to less than 15 times

DD: 20 times or more

TABLE 1

| | | Pixel | | | | | | | | | | | | |
|---|---|---|---|---|---|---|---|---|---|---|---|---|---|---|
| | | size | | | | | | Number | | | | | | |
| | | of | Photomask | | Interval | Length | Diameter | of | Coating | | | | | |
| | | sensor | Opening | Interval | A | B | C | lami- | thickness | | | Bright- | Sharp- | Produc- |
| | Sample | (μm) | (μm) | (μm) | (μm) | (μm) | (μm) | nations | (μm) | B/A | C/A | ness | ness | tivity |
| Example 1 | 1 | 200 | 185 | 15 | 6 | 50 | 194 | 8 | 400 | 8.7 | 33.8 | AA | BB | BB |
| Example 2 | 2 | 200 | 185 | 15 | 6 | 100 | 194 | 4 | 400 | 17.4 | 33.8 | AA | DD | AA |
| Example 3 | 3 | 200 | 150 | 50 | 43 | 100 | 158 | 4 | 400 | 2.4 | 3.7 | BB | BB | AA |
| Example 4 | 4 | 200 | 135 | 65 | 58 | 50 | 142 | 8 | 400 | 0.9 | 2.4 | CC | BB | BB |
| Example 5 | 5 | 200 | 115 | 85 | 79 | 50 | 121 | 8 | 400 | 0.6 | 1.5 | DD | BB | BB |
| Example 6 | 6 | 100 | 85 | 15 | 11 | 100 | 89 | 4 | 400 | 9.3 | 8.3 | AA | AA | AA |
| Example 7 | 7 | 100 | 55 | 45 | 42 | 100 | 58 | 4 | 400 | 2.4 | 1.4 | DD | AA | AA |
| Reference | 8 | 200 | — | — | — | — | — | 1 | 400 | — | — | AA | DD | AA |
| Example 1 | | | | | | | | | | | | | | |

In Table 1, “Pixel size of sensor (μm)” indicates a sidelength of a pixel of a sensor, and “Opening (μm)” under “Photomask” indicates a sidelength of an opening of a photomask.

Obviously, numerous modifications and variations of the present invention are possible in light of the above teachings. It is therefore to be understood that within the scope of the appended claims, the invention may be practiced otherwise than as specifically described herein.

What is claimed is:

1. A scintillator panel comprising:
a substrate; and
a scintillator layer provided on the substrate, the layer comprising a plurality of columnar structures,
wherein the plurality of columnar structures are independent of each other via a gap,
and the columnar structures are irradiation products.

2. The scintillator panel according to claim 1, wherein the columnar structures are each a laminate of a plurality of resin layers each comprising scintillator particles and a resin.

3. The scintillator panel according to claim 2, wherein the scintillator layer satisfies the relationships 0.1≦B/A≦20.0 and 2.0≦C/A, wherein A is an interval (μm) between the adjacent columnar structures; B is a length (μm) of one of the resin layers constituting a columnar structure in the direction in which the substrate and the resin layers are laminated; and C is a diameter (μm) of the inscribed circle of a columnar structure viewed from above the substrate.

4. The scintillator panel according to claim 2, wherein B, the length of one of the resin layers constituting each columnar structure in the direction in which the substrate and the resin layers are laminated, is in the range of 10 to 200 μm.

5. A radiation detector comprising:
a sensor substrate (I) having a plurality of light-receptive pixels; and
the scintillator panel according to claim 1, the sensor substrate (I) and the scintillator layer facing each other.

6. A radiation detector comprising:
the scintillator panel according to claim 1, wherein the substrate is a sensor substrate (I) having a plurality of light-receptive pixels; and
a substrate (II) on which a plurality of light-receptive pixels are not formed.

7. A method for manufacturing a scintillator panel, comprising:
Step I: forming a photosensitive paste layer from a photosensitive paste comprising at least scintillator particles and a photosensitive component, and exposing the photosensitive paste layer using a photomask to form a given pattern; and
Step II: removing developer-soluble portions of the exposed photosensitive paste layer.

8. The manufacturing method according to claim 7, wherein the Step I is repeated twice or more before the Step II.
